(19) United States
(12) Patent Application Publication
(10) Pub. No.: US 2024/0352587 A1
(43) Pub. Date: Oct. 24, 2024

(54) SUBSTRATE PROCESSING APPARATUS INCLUDING ELECTROSTATIC CHUCK

(71) Applicant: ASM IP Holding B.V., Almere (NL)

(72) Inventor: Nobuaki Tanabe, Kawasaki-shi (JP)

(21) Appl. No.: 18/635,185

(22) Filed: Apr. 15, 2024

Related U.S. Application Data
(60) Provisional application No. 63/460,155, filed on Apr. 18, 2023.

(51) Int. Cl. C23C 16/458; H02N 13/00

(52) U.S. Cl. CPC C23C 16/4586; H02N 13/00

(57) ABSTRACT

A substrate processing apparatus including an electrostatic chuck includes a lower electrode, an upper electrode, a first AC power supply, a first filter circuit connected to the heater, an isolation transformer connected to the heater through the first filter circuit, a second AC power supply connected to the isolation transformer, an internal electrode provided in the lower electrode, a second filter circuit, and a DC power supply, in which the DC power supply is driven under constant current control, and a secondary coil of the isolation transformer is electrically floating.

### CROSS-REFERENCE TO RELATED APPLICATIONS

This application claims priority to U.S. Provisional Patent Application Ser. No. 63/460,155 filed Apr. 18, 2023 titled SUBSTRATE PROCESSING APPARATUS INCLUDING ELECTROSTATIC CHUCK, the disclosure of which is hereby incorporated by reference in its entirety.

### FIELD OF INVENTION

The present disclosure relates to a substrate processing apparatus used for substrate processing such as film formation.

### BACKGROUND OF THE DISCLOSURE

Patent Literature 1 discloses a film forming apparatus provided with a plasma processing reaction chamber.

There is a substrate processing apparatus that supplies a material gas between a lower electrode and an upper electrode, supplies high-frequency power to the lower electrode to generate plasma between the lower electrode and the upper electrode, and performs processing on a substrate on the lower electrode. In a case where a substrate is electrostatically attracted to the lower electrode by an electrostatic chuck (ESC) in such a substrate processing apparatus, a stable chucking force is desired.

### CITATION LIST

### Patent Literature

Patent Literature 1: Japanese Unexamined Patent Application, First Publication No. 2018-93179

### SUMMARY OF THE DISCLOSURE

However, a material such as AlN constituting the lower electrode has variations in volume resistance at high temperature, and even when a constant ESC voltage is applied, the ESC current may vary, and a chucking force may become unstable. In a case where a chucking force is not stable, a stress value and uniformity of a formed film are affected. The present disclosure has been made in view of the above circumstances, and an object thereof is to provide a substrate processing apparatus with excellent stability of a chucking force.

A substrate processing apparatus including an electrostatic chuck according to an aspect of the present disclosure includes a lower electrode formed of a dielectric, an upper electrode provided to face the lower electrode, a first AC power supply connected to the upper electrode and supplying an AC power with a first frequency, a heater provided in the lower electrode and heating the lower electrode, a first filter circuit connected to the heater, an isolation transformer connected to the heater through the first filter circuit, a second AC power supply connected to the isolation transformer, an internal electrode provided in the lower electrode, a second filter circuit connected to the internal electrode, and a DC power supply connected to the internal electrode through the second filter circuit and provided for the electrostatic chuck, in which the DC power supply is driven under constant current control, and a secondary coil of the isolation transformer is in a floating state.

A substrate processing apparatus including an electrostatic chuck according to another aspect of the present disclosure includes a lower electrode formed of a dielectric, an upper electrode provided to face the lower electrode, a first AC power supply connected to the upper electrode and supplying an AC power with a first frequency, a heater provided in the lower electrode and heating the lower electrode, a first filter circuit connected to the heater, an isolation transformer connected to the heater through the first filter circuit, a second AC power supply connected to the isolation transformer, an internal electrode provided in the lower electrode, a second filter circuit connected to the internal electrode, and a DC power supply connected to the internal electrode through the second filter circuit and provided for the electrostatic chuck, in which the DC power supply is under constant voltage control, and a secondary coil of the isolation transformer is connected to a ground through a variable resistor.

According to the above-described aspects of the present disclosure, a stable chucking force can be obtained.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 is a cross-sectional view of a substrate processing apparatus including an electrostatic chuck according to a first embodiment of the present disclosure.

FIG. 2 is a diagram illustrating operations of the substrate processing apparatus including an electrostatic chuck.

FIG. 3 is an equivalent circuit diagram of the substrate processing apparatus including an electrostatic chuck according to the first embodiment.

FIG. 4 is a cross-sectional view of a substrate processing apparatus including an electrostatic chuck according to a second embodiment of the present disclosure.

FIG. 5 is an equivalent circuit diagram of the substrate processing apparatus including an electrostatic chuck according to the second embodiment.

FIG. 6 is a cross-sectional view of a substrate processing apparatus including an electrostatic chuck according to an example of the related art.

FIG. 7 is an equivalent circuit diagram of the substrate processing apparatus including an electrostatic chuck according to the example of the related art.\

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

### First Embodiment

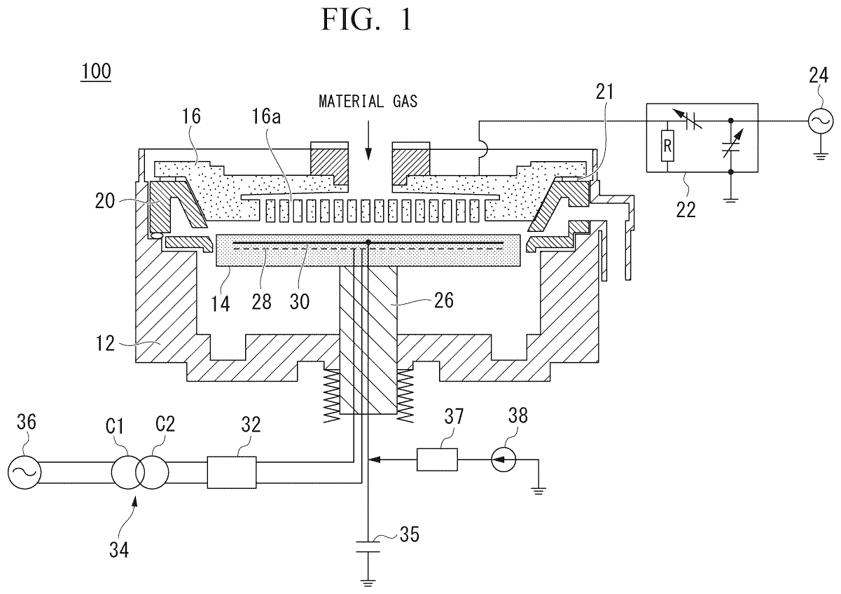

Hereinafter, a substrate processing apparatus including an electrostatic chuck according to a first embodiment of the present disclosure will be described with reference to the drawings. FIG. 1 is a cross-sectional view of a substrate processing apparatus 100 according to the first embodiment. The substrate processing apparatus 100 includes a chamber 12. A lower electrode 14 formed of a dielectric and an upper electrode 16 disposed to face the lower electrode 14 are provided in the chamber 12. The material of the lower electrode 14 is, for example, a ceramic such as AlN. The upper electrode 16 is provided with a plurality of slits 16a. A material gas is supplied between the lower electrode 14 and the upper electrode 16 through the slits 16a.

An exhaust duct 20 is fixed to the chamber 12 and the upper electrode 16 through an O-ring 21. The exhaust duct 20 surrounds a space between the upper electrode 16 and the lower electrode 14. The gas supplied between the upper electrode 16 and the lower electrode 14 and used for substrate processing is discharged to the outside of the chamber 12 through the exhaust duct 20.

The upper electrode 16 is electrically connected to a first AC power supply 24 through a matching unit 22. The first AC power supply 24 provides an AC power at a frequency in the range of, for example, 1 MHz to 30 MHz. The frequency in the range of 1 MHz to 30 MHz is an example of a “first frequency”. The frequency of 1 MHz to 30 MHz is referred to as a high radio frequency (HRF). In the present embodiment, as an example, the first AC power supply 24 supplies the AC power of 13.56 MHz. In addition, the substrate processing apparatus 100 may include a third AC power supply, which is not illustrated in the drawing, in addition to the first AC power supply 24. The third AC power supply in this case supplies an AC power with a frequency in the range of 100 kHz to 1000 kHz. This frequency in the range of 100 kHz to 1000 kHz is referred to as a low radio frequency. The third AC power supply is also electrically connected to the upper electrode 16 through the matching unit 22. In the present embodiment, as an example, the third AC power supply supplies the AC power of 430 kHz.

The lower electrode 14 is supported by a support portion (shaft) 26. The lower electrode 14 and the support portion 26 are susceptors integrally formed with each other. The lower electrode 14 may be referred to as an RF electrode.

A heater 28 for heating the lower electrode 14 is provided in the lower electrode 14. The heater 28 is formed, for example, in a spiral shape when seen in a plan view. The heater 28 is connected to a first filter circuit 32 by wiring passing through the support portion 26. An isolation transformer 34 is connected to the heater 28 through the first filter circuit 32. Specifically, the first filter circuit 32 is connected to a secondary coil C2 of the isolation transformer 34. The secondary coil C2 is electrically floating. In addition, the first filter circuit 32 is grounded in a DC-insulated state. The first filter circuit 32 is, for example, a low-pass filter. The first filter circuit 32 reduces high frequency noise. A second AC power supply 36 used in the heater 28 is connected to the isolation transformer 34. Specifically, the second AC power supply 36 is connected to a primary coil C1 of the isolation transformer 34. When the second AC power supply 36 supplies a current to the heater 28, the lower electrode 14 is heated, and a substrate (not illustrated) placed on the lower electrode 14 is also heated. The second AC power supply 36 applies an AC power with, for example, a frequency of 50 Hz or 60 Hz.

An internal electrode 30 is provided in the lower electrode 14. The material of the internal electrodes 30 is, for example, a high melting point metal such as tungsten, tantalum, molybdenum, niobium, ruthenium, and hafnium. The shape of the internal electrode 30 is a wire net shape or a punching metal shape. The internal electrode 30 is connected to a second filter circuit 37 by wiring passing through the support portion 26. A DC power supply 38 is connected to the second filter circuit 37. The DC power supply 38 is provided for the electrostatic chuck and is driven under constant current control. The DC power supply 38 supplies a constant electric static chuck (ESC) current to the internal electrode 30 by constant current control in order to provide the electrostatic chuck. In addition, the internal electrode 30 is connected to the ground through a blocking capacitor 35.

In the substrate processing apparatus 100 of the first embodiment, a secondary coil C2 of the isolation transformer 34 is electrically floating. In addition, the first filter circuit 32 is DC-insulated. For this reason, a leakage current (ground fault current) does not flow through the heater 28 to a heater power supply side. In addition, the leakage current does not flow to the heater side, and thus the DC power supply 38 can apply a constant ESC current from the lower electrode 14 to the upper electrode 16 by constant current control in the substrate processing apparatus 100. For this reason, the ESC current can be stabilized.

### Operations of Substrate Processing Apparatus

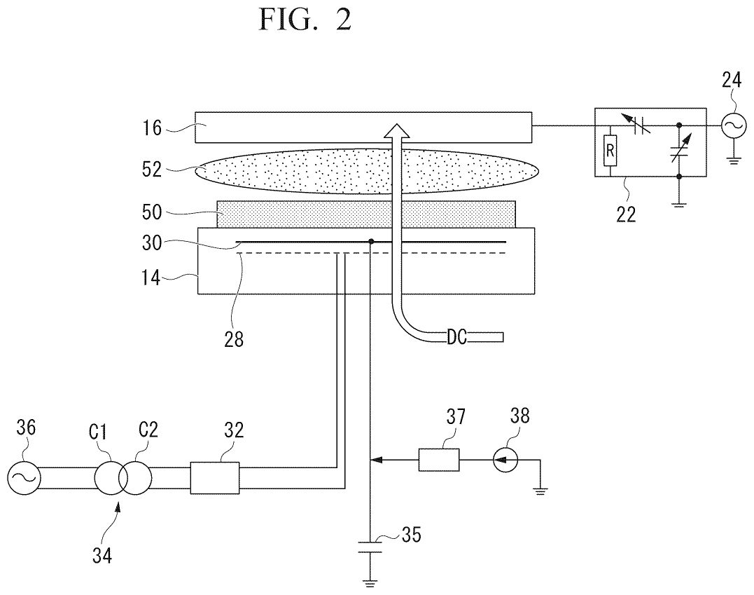

Operations of the substrate processing apparatus during substrate processing will be described. FIG. 2 is a diagram simply expressing the configuration of FIG. 1 in order to facilitate the description of operations during substrate processing. Substrate processing is started in a state where a substrate 50 is placed on the lower electrode 14. The substrate 50 is, for example, a Si wafer. The substrate 50 is heated to a predetermined temperature by the heater 28. While supplying a material gas between the upper electrode 16 and the lower electrode 14, the AC power of the first frequency is supplied to the upper electrode 16 by the first AC power supply 24. Thereby, a plasma 52 is generated between the upper electrode 16 and the lower electrode 14. When a ESC voltage is applied to the internal electrode 30 by the DC power supply 38 in this state, a ESC (DC) current flows through a plasm between electrodes to the grounded upper electrode 16 side and Johnsen-Rahbeck force is generated by the induced charged polarization at an interfacial gap between the substrate 50 and the lower electrode 14, and the substrate 50 is electrostatically absorbed to the lower electrode 14. Thereby, electrostatic chucking can be performed.

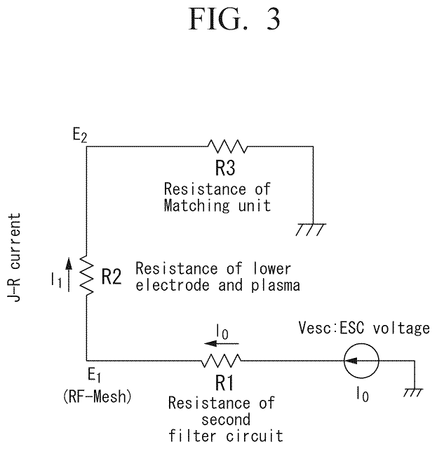

FIG. 3 illustrates an equivalent circuit during an operation of the substrate processing apparatus 100. The secondary coil C2 of the isolation transformer 34 is electrically floating. As illustrated in FIG. 3, the equivalent circuit during the electrostatic chucking operation of the substrate processing apparatus 100 is a circuit constituted by a resistor R1 of the second filter circuit 37, a resistor R2 of the lower electrode 14 and the plasma, and a resistor R3 of the matching unit 22. In the present embodiment, a current is not branched out, and thus the ESC current can be stably controlled by constant current control. The Johnsen-Rahbek (JR) chucking force is known to be proportional to a current value. Thus, the substrate processing apparatus 100 can obtain a stable chucking force by a stable ESC current.

The substrate processing apparatus 100 according to the first embodiment is in a state where the secondary coil of the isolation transformer is electrically floating. For this reason, a leakage current can be basically set to zero. Further, in the substrate processing apparatus 100 according to the first embodiment, the DC power supply 38 is driven under constant current control in a state where the leakage current is substantially zero. For this reason, a stable chucking force can be obtained.

The content of processing performed by the substrate processing apparatus 100 according to the first embodiment is not particularly limited as long as plasma processing is accompanied. The substrate processing apparatus 100 of the present embodiment may be used as a plasma-enhanced atomic layer deposition apparatus (PEALD apparatus) or as a plasma-enhanced chemical vapor deposition apparatus (PECVD apparatus).

### Second Embodiment

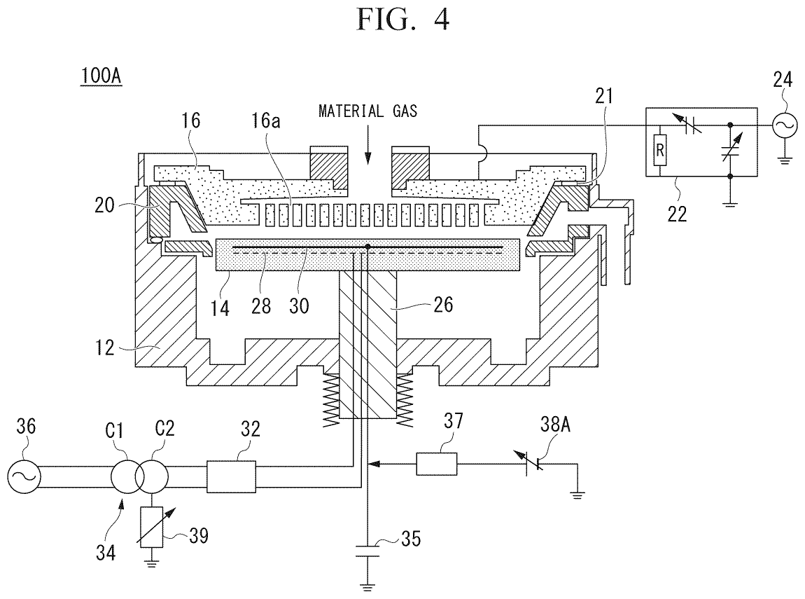

Hereinafter, a substrate processing apparatus according to a second embodiment of the present disclosure will be described with reference to the drawings. FIG. 4 is a cross-sectional view of a substrate processing apparatus 100A according to the second embodiment. The substrate processing apparatus 100A includes a chamber 12. A lower electrode 14 formed of a dielectric and an upper electrode 16 disposed to face the lower electrode 14 are provided in the chamber 12. The material of the lower electrode 14 is, for example, a ceramic such as AlN. The upper electrode 16 is provided with a plurality of slits 16a. A material gas is supplied between the lower electrode 14 and the upper electrode 16 through the slits 16a.

An exhaust duct 20 is fixed to the chamber 12 and the upper electrode 16 through an O-ring 21. The exhaust duct 20 surrounds a space between the upper electrode 16 and the lower electrode 14. A gas supplied between the upper electrode 16 and the lower electrode 14 and used for substrate processing is discharged to the outside of the chamber 12 through an exhaust duct 20.

The upper electrode 16 is electrically connected to a first AC power supply 24 through a matching unit 22. The first AC power supply provides an AC power at a frequency in the range of, for example, 1 MHz to 30 MHz. The frequency in the range 1 MHz to 30 MHz is an example of a “first frequency”. In the present embodiment, for example, the AC power of 13.56 MHz is supplied. In addition, the substrate processing apparatus 100 A may include a third AC power supply, which is not illustrated in the drawing, in addition to the first AC power supply 24. The third AC power supply in this case supplies an AC power with a frequency in the range of, for example, 100 kHz to 1000 kHz. The third AC power supply is also electrically connected to the upper electrode 16 through the matching unit 22. In the present embodiment, as an example, the third AC power supply supplies the AC power of 430 KHz.

The lower electrode 14 is supported by a support portion 26. The lower electrode 14 and the support portion 26 are susceptors integrally formed with each other. The lower electrode 14 may be referred to as an RF electrode.

A heater 28 for heating the lower electrode 14 is provided in the lower electrode 14. The heater 28 is formed, for example, in a spiral shape when seen in a plan view. The heater 28 is connected to the first filter circuit 32 by wiring passing through the support portion 26. An isolation transformer 34 is connected to the heater 28 through the first filter circuit 32. Specifically, the first filter circuit 32 is connected to a secondary coil C2 of the isolation transformer 34. The secondary coil C2 is connected to the ground through a variable resistor 39. In addition, the first filter circuit 32 is grounded in a DC-insulated state. The first filter circuit 32 is, for example, a low-pass filter. The first filter circuit 32 reduces high frequency noise. A second AC power supply 36 used in the heater 28 is connected to the isolation transformer 34. Specifically, the second AC power supply 36 is connected to a primary coil C1 of the isolation transformer 34. When the second AC power supply 36 supplies a current to the heater 28, the lower electrode 14 is heated, and a substrate (not illustrated) placed on the lower electrode 14 is also heated. The second AC power supply 36 applies an AC power with, for example, a frequency of 50 Hz or 60 Hz to the heater 28.

An internal electrode 30 is provided in the lower electrode 14. The material of the internal electrode 30 is, for example, a high melting point metal such as tungsten, tantalum, molybdenum, niobium, ruthenium, and hafnium. The internal electrode 30 is shaped like a wire net or a punching metal. The internal electrode 30 is connected to a second filter circuit 37 by wiring passing through the support portion 26. A DC power supply 38A is connected to the second filter circuit 37. The DC power supply 38A is provided for the electrostatic chuck and is driven under constant voltage control. In addition, the internal electrode 30 is connected to the ground through a blocking capacitor 35.

In the substrate processing apparatus 100A of the second embodiment, the secondary coil of the insulating transformer is grounded through the variable resistor, and the DC power supply 38A is driven under constant voltage control. For this reason, the variable resistance compensates for variations in a current due to variations in volume resistance between heaters to a constant level and control a chucking force by the ESC current within a certain range. In general, DC discharge is likely to occur around the lower electrode 14 when the ESC voltage is raised above a certain level in order to compensate for lack of the chucking force of heater with high leakage current. By using the substrate processing apparatus 100A of the second embodiment, it is possible to perform control chucking force (ESC current) with a constant low ESC voltage and to suppress DC discharge.

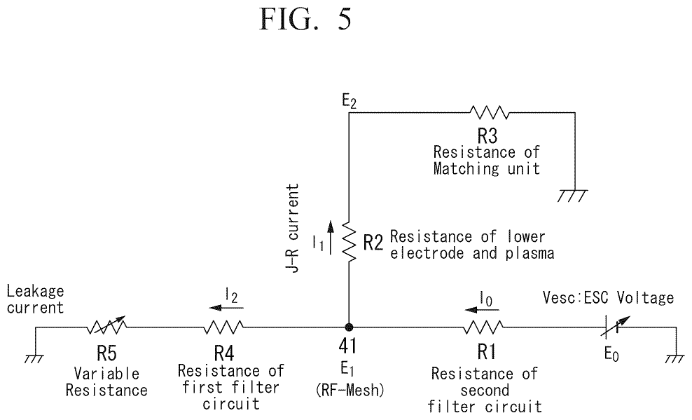

FIG. 5 illustrates an equivalent circuit during an operation of the substrate processing apparatus 100A. The secondary coil C2 of the isolation transformer 34 is connected to the ground (grounded) through the variable resistor. An equivalent circuit during the electrostatic chuck operation of the substrate processing apparatus 100A is a circuit constituted by a resistor R1 of the second filter circuit 37, a resistor R2 of the lower electrode 14 and the plasma, a resistor R3 of the matching unit 22, a volume resistance R4 of the lower electrode 14, and the variable resistor 39. In this equivalent circuit, the resistor R1 of the second filter circuit 37 is connected to a node 41, the resistor R2 of the lower electrode 14 and the plasma is connected to the node 41, and the resistor R4 of the first filter circuit 32 is connected to the node 41. In the present embodiment, by controlling the variable resistor R5, the leakage current flowing to the R4 side can be corrected. Thereby, it is possible to set the ESC current to be in a predetermined range and stabilize a chucking force.

The content of processing by the substrate processing apparatus 100A according to the second embodiment is not particularly limited as long as plasma processing is accompanied. The substrate processing apparatus 100A of the present embodiment may be used as a plasma-enhanced atomic layer deposition apparatus (PEALD apparatus) or as a plasma-enhanced chemical vapor deposition apparatus (PECVD apparatus).

### (Example of Related Art)

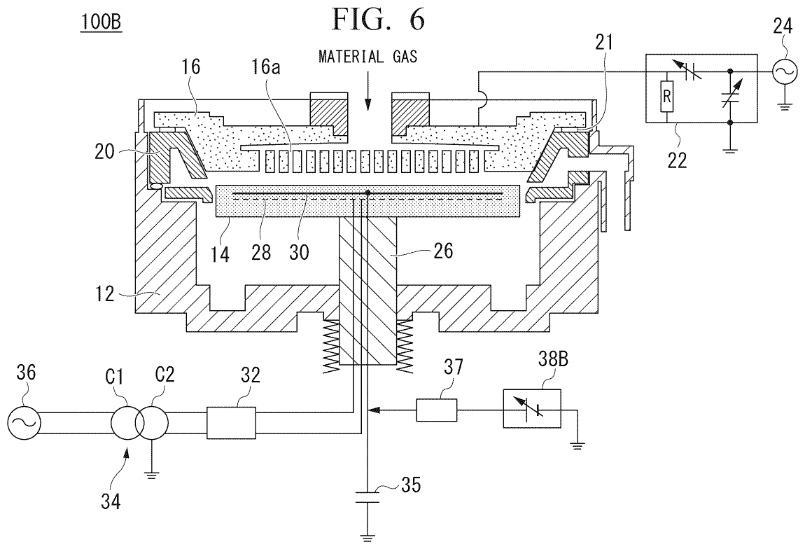

For comparison with the configuration of the present disclosure described above, a substrate processing apparatus according to an example of the related art will be described below with reference to the drawings. FIG. 6 is a cross-sectional view of a substrate processing apparatus 100B according to an example of the related art. The substrate processing apparatus 100B includes a chamber 12. A lower electrode 14 formed of a dielectric and an upper electrode 16 disposed to face the lower electrode 14 are provided in the chamber 12. The material of the lower electrode 14 is, for example, a ceramic such as AlN. The upper electrode 16 is provided with a slit 16a. A material gas is supplied between the lower electrode 14 and the upper electrode through the slit 16a.

An exhaust duct 20 is fixed to the chamber 12 and the upper electrode 16 through an O-ring. The exhaust duct surrounds a space between the upper electrode 16 and the lower electrode 14. A gas supplied between the upper electrode 16 and the lower electrode 14 and used for substrate processing is discharged to the outside through the exhaust duct 20.

The upper electrode 16 is connected to a first AC power supply 24 through a matching unit 22. The first AC power supply supplies an AC power with a frequency in the range of, for example, 1 MHz to 30 MHz.

The lower electrode 14 is supported by a support portion 26. The lower electrode 14 and the support portion 26 are susceptors integrally formed with each other.

A heater 28 for heating the lower electrode 14 is provided in the lower electrode 14. The heater 28 is provided, for example, in a spiral shape when seen in a plan view. The heater 28 is connected to the first filter circuit 32 by wiring passing through the support portion 26. An isolation transformer 34 is connected to the heater 28 through the first filter circuit 32. Specifically, the first filter circuit 32 is connected to a secondary coil C2 of the isolation transformer 34. The secondary coil C2 is connected to the ground, unlike the first embodiment. A second AC power supply 36 used in the heater 28 is connected to the isolation transformer 34. Specifically, the second AC power supply 36 is connected to a primary coil C1 of the isolation transformer 34. When the second AC power supply 36 supplies a current to the heater 28, the lower electrode 14 is heated, and the substrate on the lower electrode 14 is also heated.

An internal electrode 30 is provided in the lower electrode 14. The internal electrode 30 is connected to a second filter circuit 37 by wiring passing through the support portion 26. A DC power supply 38B is connected to the second filter circuit 37. The DC power supply 38B is provided for the electrostatic chuck. The DC power supply 38B applies a constant voltage to the internal electrode 30 by constant voltage control in order to provide the electrostatic chuck. In addition, the internal electrode 30 is connected to the ground through a blocking capacitor 35.

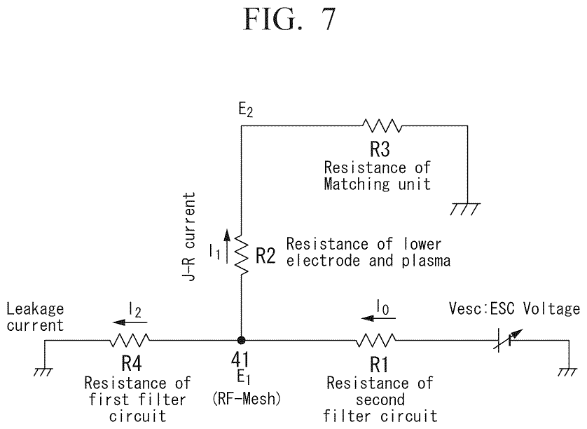

FIG. 7 illustrates an equivalent circuit during an operation of the substrate processing apparatus 100B according to the example of the related art. In the substrate processing apparatus 100B, the secondary coil C2 is connected to the ground. For this reason, when heated by the heater 28, a resistance value R4 of the lower electrode 14 decreases, and a leak current flows through the grounded circuit of the heater power supply on the heater 28 side. In the example of the related art, the DC power supply 38B is driven under constant voltage control, and thus the leakage current fluctuates according to the volume resistance R4 of the lower electrode 14. For this reason, unlike the embodiments described above, the ESC current may fluctuate due to variations for each heater.

The substrate processing apparatuses according to the embodiments of the present disclosure have been described above in detail while comparing them with the example of the related art. Note that the technical scope of the present disclosure is not limited to the above-described embodiments, and various modifications can be made without departing from the scope of the present disclosure. In addition, the components in the above-described embodiments can be appropriately replaced with well-known components without departing from the scope of the present disclosure, and the above-described embodiments may be combined as appropriate.

1. A substrate processing apparatus including an electrostatic chuck, comprising:
a lower electrode formed of a dielectric material;
an upper electrode provided to face the lower electrode;
a first AC power supply electrically connected to the upper electrode and supplying an AC power with a first frequency;
a heater provided in the lower electrode and configured to heat the lower electrode;
a first filter circuit connected to the heater;
an isolation transformer connected to the heater through the first filter circuit;
a second AC power supply connected to the isolation transformer;
an internal electrode provided in the lower electrode;
a second filter circuit connected to the internal electrode; and
a DC power supply connected to the internal electrode through the second filter circuit and provided for an electrostatic chuck,
wherein the DC power supply is driven under constant current control, and
a secondary coil of the isolation transformer is electrically floating.

2. The substrate processing apparatus including an electrostatic chuck according to claim 1, wherein the first AC power supply supplies the AC power with a frequency in a range of 1 MHz to 30 MHz to the upper electrode.

3. The substrate processing apparatus including an electrostatic chuck according to claim 2, wherein an AC power with a frequency in a range of 100 kHz to 1000 kHz is further supplied to the upper electrode.

4. The substrate processing apparatus including an electrostatic chuck according to claim 1, wherein the second AC power supply supplies an AC power of 50 Hz or 60 Hz to the heater.

5. The substrate processing apparatus including an electrostatic chuck according to claim 1, wherein the internal electrode is connected to a ground through a capacitor.

6. A substrate processing apparatus including an electrostatic chuck, comprising:
a lower electrode formed of a dielectric;
an upper electrode provided to face the lower electrode;
a first AC power supply connected to the upper electrode and supplying an AC power with a first frequency;
a heater provided in the lower electrode and heating the lower electrode;
a first filter circuit connected to the heater;
an isolation transformer connected to the heater through the first filter circuit;
a second AC power supply connected to the isolation transformer;
an internal electrode provided in the lower electrode;
a second filter circuit connected to the internal electrode; and
a DC power supply connected to the internal electrode through the second filter circuit and provided for an electrostatic chuck,
wherein the DC power supply is driven under constant voltage control, and
a secondary coil of the isolation transformer is connected to a ground through a variable resistor.

7. The substrate processing apparatus including an electrostatic chuck according to claim 6, wherein the first AC power supply supplies the AC power with a frequency in a range of 1 MHz to 30 MHz to the upper electrode.

8. The substrate processing apparatus including an electrostatic chuck according to claim 7, wherein an AC power with a frequency in a range of 100 kHz to 1000 kHz is further supplied to the upper electrode.

9. The substrate processing apparatus including an electrostatic chuck according to claim 6, wherein the second AC power supply supplies an AC power of 50 Hz or 60 Hz to the heater.

10. The substrate processing apparatus including an electrostatic chuck according to claim 6, wherein the internal electrode is connected to a ground through a capacitor.
